(19) United States
(12) Patent Application Publication
(10) Pub. No.: US 2007/0298610 A1
(43) Pub. Date: Dec. 27, 2007

(54) Method for producing electro-optical apparatus

(75) Inventors: Takushi Itagaki, Chino-shi (JP); Naoto Nishimura, Fujimi-machi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/820,325

(22) Filed: Jun. 19, 2007

(30) Foreign Application Priority Data
Jun. 21, 2006 (JP) 2006-171007
Feb. 28, 2007 (JP) 2007-048615

(51) Int. Cl. H01L 21/44

(52) U.S. Cl. 438/679; 438/683

(57) ABSTRACT

A method for producing an electro-optical apparatus includes forming a WSi film by sputtering including bombarding a target with plasma ions of an atmosphere injected into a vacuum chamber under reduced pressure to eject particles from the target and depositing the particles on a substrate to be used to form the electro-optical apparatus. The WSi film is formed in such a manner that the average deposition rate of the WSi film deposited on the substrate is equal to or higher than an average deposition rate at the limit of discharge maintenance in sputtering and 35 Å/s or less.

### BACKGROUND

1. Technical Field

The present invention relates to a method for producing an electro-optical apparatus. In particular, the invention relates to a method for producing an electro-optical apparatus, the method including forming a WSi film by sputtering on a substrate to be used to form an electro-optical apparatus.

2. Related Art

In general, when transistors for switching pixels or for driving circuits are formed on a substrate to constitute an electro-optical apparatus such as a liquid crystal display, in order to prevent the malfunction of the transistors due to light incident on the transistors, a light-shading film having a light-blocking effect on at least visible light is formed near the transistors. An example of the light-shading film is a metal silicide film such as a tungsten silicide (WSi) film.

In the case of the WSi film formed by sputtering, although the WSi film has an amorphous structure composed of tungsten and silicon, the WSi film is subjected to heat treatment such as annealing to crystallize, thereby causing internal stress in the WSi film. Thus, in the case where an interlayer insulating film is formed after the formation of the WSi film on the substrate, and then annealing is performed after the formation of a semiconductor layer constituting transistors, a crack is liable to occur due to the internal stress of the WSi film when the substrate is cooled to room temperature. When the crack reaches the semiconductor layer or a conductive layer serving as a gate electrode, the crack causes the malfunction of the electro-optical apparatus.

As a method for suppressing the occurrence of a crack, JP-A-9-33950 discloses a method for suppressing internal stress by forming a thin light-shading film (black matrix) having a double-layered structure.

However, in the art disclosed in JP-A-9-33950, the number of film-forming steps is disadvantageously increased in order to form the double-layered light-shading film. Furthermore, when the light-shading film has a small thickness, sufficient light-blocking effect is not exerted.

### SUMMARY

An advantage of some aspects of the invention is that the occurrence of a crack in an insulating layer, a conductive layer, and a semiconductor layer due to internal stress in a WSi film is prevented by a method for producing an electro-optical apparatus.

A method according to an aspect of the invention for producing an electro-optical apparatus includes forming a WSi film by sputtering including bombarding a target with plasma ions of an atmosphere injected into a vacuum chamber under reduced pressure to eject particles from the target and depositing the particles on a substrate to be used to form the electro-optical apparatus, wherein the WSi film is formed in such a manner that the average deposition rate of the WSi film deposited on the substrate is equal to or higher than an average deposition rate at the limit of discharge maintenance in sputtering and 35 Å/s or less.

The structure of the aspect of the invention can reduce the number of critical cracks extending to a conductive layer and a semiconductor layer to ⅓ of that in the known art, thereby markedly suppressing the occurrence of the malfunction of the electro-optical apparatus due to the crack in the conductive layer and the semiconductor layer. Furthermore, the WSi film is formed by a single sputtering process similar to the known art. Thus, there is no need to increase the number of steps.

In accordance with the aspect of the invention, the average deposition rate of the WSi film is preferably equal to or higher than an average deposition rate at the limit of discharge maintenance in sputtering and 30 Å/s or less.

In this case, the number of critical cracks decreases to 1/10 or less of that in the known art. Furthermore, no minute crack that does not extend to the conductive layer and the semiconductor layer occurs. That is, there is no propagation of the minute crack to the conductive layer and the semiconductor layer, thereby further improving the reliability of the electro-optical apparatus.

Furthermore, in accordance with the aspect of the invention, the WSi film is preferably formed while the substrate is heated in the range of 250° C. to 400° C. in the vacuum chamber.

In this case, WSi is deposited on the substrate heated to a temperature close to the crystallization temperature of WSi; hence, a dense WSi film can be formed compared with the case without heating. As a result, the structure of the WSi film formed by sputtering approaches the structure of the WSi film crystallized by subsequent heat treatment, thereby further reducing internal stress in the WSi film after heat treatment and thus further suppressing the occurrence of a crack due to the internal stress in the WSi film.

Furthermore, in accordance with the aspect of the invention, magnetron sputtering is preferably used, the position of the generation of the plasma of the atmosphere injected into the vacuum chamber is controlled by using a magnetic field generated by an electromagnet, and the average deposition rate of the WSi film is controlled by controlling the strength of the magnetic field generated by the electromagnet.

In this case, the average deposition rate of the WSi film can be controlled regardless of the minimum power to maintain a discharge for sputtering.

Furthermore, the average deposition rate at the limit of discharge maintenance in sputtering is preferably 7 Å/s.

In this case, the discharge during sputtering is maintained, and a film can be stably formed.

### BRIEF DESCRIPTION OF THE DRAWINGS

The invention will be described with reference to the accompanying drawings, wherein like numbers reference like elements.

FIG. 1 is a plan view of a liquid crystal display when a TFT array substrate is viewed from an opposite substrate side together with components disposed on the TFT array substrate.

FIG. 2 is a cross-sectional view taken along line H-H′ in FIG. 1.

FIG. 3 is an equivalent circuit illustrating a plurality of pixels arrayed in a matrix including various elements, lines, and the like.

FIG. 4 is a cross-sectional view illustrating a TFT portion of a pixel region of the TFT array substrate.

FIG. 5 is a cross-sectional view illustrating the TFT portion of a sampling circuit.

FIG. 6 is a schematic cross-sectional view illustrating the structure of a sputtering apparatus.

FIG. 7 is a graph showing the relationship between the average deposition rate of a WSi film and the number of critical cracks.

FIG. 8 is a graph showing the relationship between the average deposition rate of the WSi film and the number of minute cracks.

### DESCRIPTION OF EXEMPLARY EMBODIMENTS

Embodiments of the invention will be described below with reference to the drawings. In the following embodiments, a liquid crystal display is used as an electro-optical apparatus according to an aspect of the invention. Components are shown at different scales so as to be recognizable in the drawings.

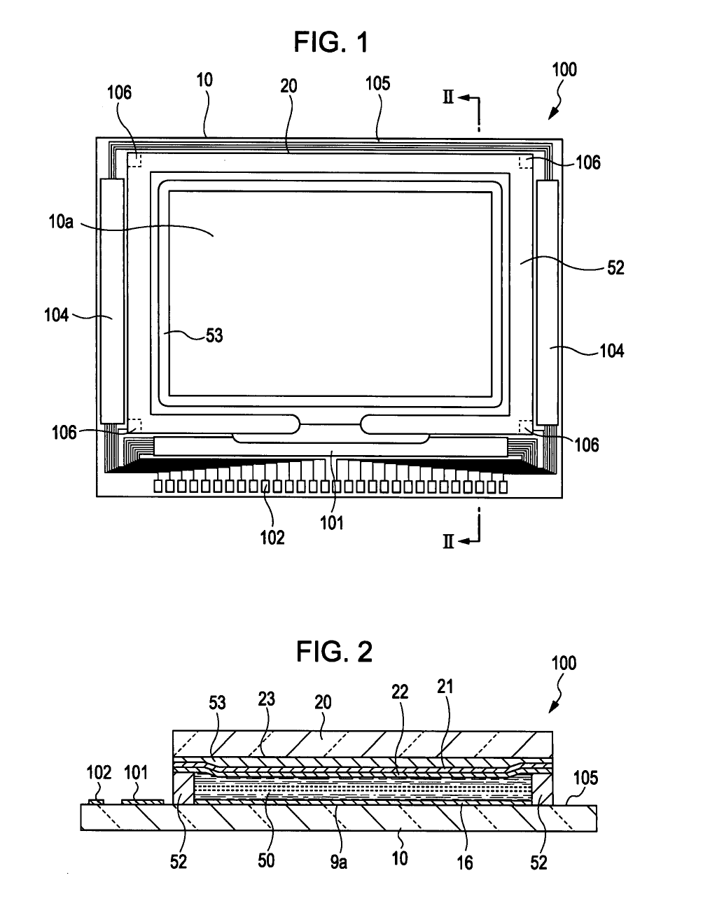

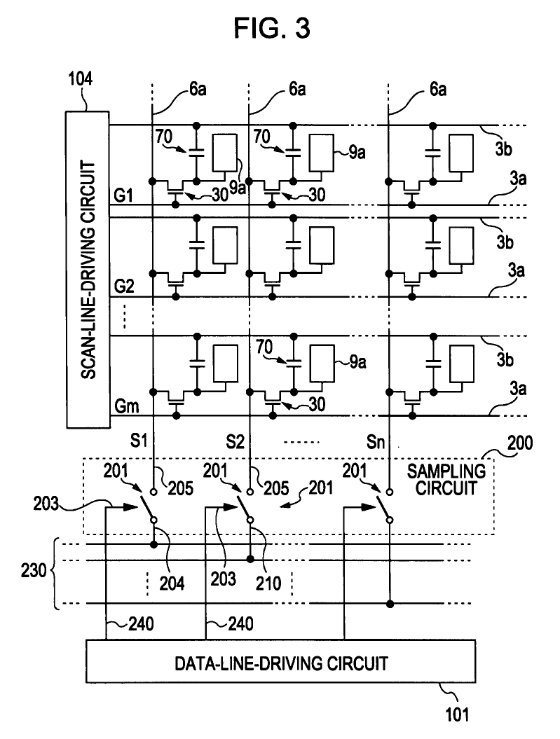

The entire structure of an electro-optical apparatus 100 according to this embodiment of the invention will be described with reference to FIGS. 1 to 3. FIG. 1 is a plan view of the liquid crystal display when a TFT array substrate is viewed from an opposite substrate side together with components disposed on the TFT array substrate. FIG. 2 is a cross-sectional view taken along line H-H′ in FIG. 1. FIG. 3 is an equivalent circuit illustrating a plurality of pixels arrayed in a matrix, the pixels constituting an image displaying region of the electro-optical apparatus, the pixels including various elements, lines, and the like. In this embodiment, a TFT-active-matrix transmissive liquid crystal display including a driving circuit is exemplified as an electro-optical apparatus. The term “TFT” defined here refers to a thin-film transistor for pixel switching.

The electro-optical apparatus 100 includes a pair of transparent TFT array substrate 10 and opposite substrate 20; and a liquid crystal layer 50 disposed between the TFT array substrate 10 and the opposite substrate 20. Changing the orientation of the liquid crystal layer 50 modulates light incident on an image-displaying region 10a from the opposite substrate 20 side. The modulated light emerges from the TFT array substrate 10 to display an image on the image-displaying region 10a.

As shown in FIGS. 1 and 2, in the electro-optical apparatus 100 according to this embodiment, the TFT array substrate 10 is opposite the opposite substrate 20. The TFT array substrate 10 is bonded to the opposite substrate 20 with a seal 52 disposed in a seal region surrounding the image-displaying region 10a. The liquid crystal layer 50 is disposed between the TFT array substrate 10 and the opposite substrate 20. The seal 52 includes gap materials, such as glass fibers or glass beads, dispersed therein in order to achieve a predetermined distance between the TFT array substrate 10 and the opposite substrate 20. The gap materials may be included in the liquid crystal layer 50.

A frame light-shading film 53 is formed in a frame region on the opposite substrate 20 side, the frame region being located along the inner side of the seal region including the seal 52 and specifying the periphery of the image-displaying region 10a. The frame light-shading film 53 may be partially or entirely formed as a built-in light-shading film on the TFT array substrate 10 side.

Among peripheral regions of the image-displaying region 10a, in a peripheral region located outside the seal region including the seal 52, a data-line-driving circuit 101 and terminals for connection with an external circuit 102 are disposed along one side of the TFT array substrate 10. Scan-line-driving circuits 104 are disposed along two sides adjacent to this side. A plurality of lines for connection between the scan-line-driving circuits 104 disposed at both sides of the image-displaying region 10a are formed along the remaining one side of the TFT array substrate 10. As shown in FIG. 1, interconnecting conductors 106 serving as conductive terminals for connection between both substrates are located at four corners of the opposite substrate 20. Interconnecting conductive terminals are disposed at regions of the TFT array substrate 10 opposite the corners. These electrically connect the TFT array substrate 10 to the opposite substrate 20.

In particular, in this embodiment, a sampling circuit 200 for sampling an image signal fed from the data-line-driving circuit 101 is located in the frame region composed of the frame light-shading film 53. That is, circuit elements, such as TFTs 201, described below constituting the sampling circuit 200 are arranged in the frame region.

As shown in FIG. 2, an alignment layer 16 is formed on pixel electrodes 9a after the formation of the TFTs for pixel switching and leads such as scan lines and data lines on the TFT array substrate 10. An opposite electrode 21, a light-shading film 23 in the form of a grid or stripes, and an uppermost alignment layer 22 are formed on the opposite substrate 20. The alignment layers 16 and 22 are located on surfaces of the TFT array substrate 10 and the opposite substrate 20 in contact with the liquid crystal layer 50 and are each formed of an inorganic alignment layer composed of an inorganic material such as SiO₂, SiO, or MgF₂ or an organic alignment layer composed of a polyimide or the like. The liquid crystal layer 50 is composed of, for example, a liquid crystal containing at least one type of nematic liquid crystal. The liquid crystal layer 50 has a predetermined orientation state between the pair of the alignment layers 16 and 22.

A polarizing film, a retardation film, a polarizing plate, and the like are each arranged in a predetermined direction on the incident light side of the opposite substrate 20 and on the outgoing light side of the TFT array substrate 10 in response to an operation mode, such as a twisted nematic (TN) mode, a super twisted nematic (STN) mode, a double-STN (D-STN) mode, or a vertical alignment (VA) mode, and a normally white mode or a normally black mode.

The electrical structure of the electro-optical apparatus will be described below with reference to FIG. 3. As shown in FIG. 3, each of the plurality of pixels arrayed in a matrix constituting the image-displaying region 10a of the electro-optical apparatus 100 according to this embodiment includes the pixel electrode 9a and a TFT 30 for controlling switching of the pixel electrode 9a. Data lines 6a into which image signals are fed are electrically connected to sources of the TFTs 30.

In the peripheral region located outside the image-displaying region 10a, an end of each of the data lines 6a (lower side in FIG. 3) is electrically connected to the drain 205 of each TFT 201 constituting the sampling circuit 200. Image signal lines 230 are electrically connected to sources of the TFTs 201 constituting the sampling circuit 200. Sampling-circuit-driving signal lines 240 electrically connected to the data-line-driving circuit 101 are electrically connected to gates of the TFTs 201 constituting the sampling circuit 200. Image signals S1, S2, . . . , and Sn fed through the image signal lines 230 are sampled by the sampling circuit 200 to be fed into the data lines 6a in response to sampling-circuit-driving signals fed from the data-line-driving circuit 101 through the sampling-circuit-driving signal lines 240. The image signals S1, S2, . . . , and Sn fed into the data lines 6a may be sequentially fed into the lines in that order.

Scan lines 3a are electrically connected to gates of the pixel-switching TFTs 30. Pulsed scan signals G1, G2, . . . , and Gm are applied to the scan lines 3a with the scan-line-driving circuits 104 at predetermined timing. The pixel electrodes 9a are electrically connected to drains of the TFTs 30. The image signals S1, S2, . . . , and Sn fed from the data lines 6a are written in predetermined timing by closing switches of the TFTs 30 serving as switching elements for a specific period of time. The image signals S1, S2, . . . , and Sn written into the liquid crystal, which is an example of an electro-optical material, at predetermined levels through the pixel electrodes 9a are held for a specific period of time between the liquid crystal and the opposite electrode 21 formed on the opposite substrate 20. The liquid crystal modulates light by changing the orientation and order of molecules in response to potential levels applied, thereby displaying gray shades. In the case of the normally white mode, incident-light transmittance is reduced in response to a voltage applied to each pixel. In the case of the normally black mode, incident-light transmittance is increased in response to a voltage applied to each pixel. Consequently, overall, light beams in response to the image signals emerge from the electro-optical apparatus. To prevent the leakage of the image signals held, storage capacitors 70 are each formed in parallel with a corresponding one of liquid crystal capacitors formed between the pixel electrodes 9a and the opposite electrode 21. Capacitor lines 3b including fixed potential sides of capacitor electrodes of the storage capacitors 70 and to which a constant potential is applied are formed in parallel with the scan lines 3a.

The electro-optical apparatus 100 according to this embodiment may be a liquid crystal panel operating in the super twisted nematic (STN) mode, the double-STN (D-STN) mode, or the vertical alignment (VA) mode; or a liquid crystal panel including a pair of electrodes on one substrate, for example, an in-plane switching mode liquid crystal panel.

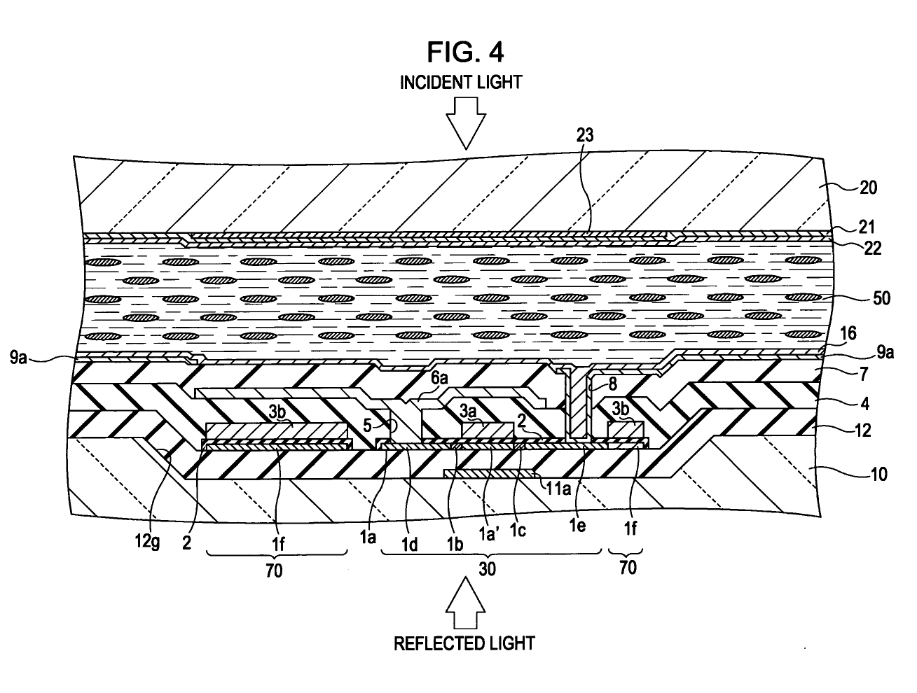

The specific structure of the electro-optical apparatus which includes the data lines 6a, the scan lines 3a, the capacitor lines 3b, the TFTs 30, and the like and in which the above-described circuit operation is performed will be described below with reference to FIG. 4. FIG. 4 is a cross-sectional view of one of the pixel-switching TFTs 30 each formed in a corresponding one of the pixels.

The electro-optical apparatus 100 includes, as described above, the transparent TFT array substrate 10 composed of, for example, quartz or glass; and the transparent opposite substrate 20 located opposite the TFT array substrate 10, the opposite substrate 20 being composed of, for example, quartz or glass. As shown in FIG. 4, a multilayer structure including various constituents, such as the TFT 30, the pixel electrodes 9a, and the alignment layer 16 is formed on the TFT array substrate 10. A groove 12g, which is a depression, is formed on the surface of the liquid crystal layer 50 side of the TFT array substrate 10. The data line 6a, the scan line 3a, the capacitor lines 3b, and the TFT 30 are stacked on the bottom of the groove 12g.

A first layer including a lower light-shading film 11a, a second layer formed on the first layer and including the TFTs 30, the scan lines 3a, and the capacitor lines 3b, a third layer formed on the second layer and including the data lines 6a, and a fourth layer formed on the third layer and including the pixel electrodes 9a are formed on the surface of the liquid crystal layer 50 side of the TFT array substrate 10. A first interlayer insulating film 12 is formed between the first and second layers. A second interlayer insulating film 4 is formed between the second and third layers. A third interlayer insulating film 7 is formed between the third and fourth layers. The first interlayer insulating film 12, the second interlayer insulating film 4, and the third interlayer insulating film 7 are each composed of a silicate glass material, such as nonsilicate glass (NSG), phosphorus silicate glass (PSG), borosilicate glass (BSG), or boron phosphorus silicate glass (BPSG), silicon nitride, or silicon oxide.

Each of the lower light-shading films 11a in the first layer is located at a position so as to overlap a corresponding one of the TFTs 30 when viewed from the TFT array substrate 10 side. Each of the lower light-shading film 11a prevents the corresponding TFT 30 from being exposed to reflected light from the TFT array substrate 10 side. The lower light-shading films 11a are each composed of tungsten silicide (hereinafter, referred to as “WSi”), which is opaque silicide having a high melting point, and each have a light-blocking effect. The lower light-shading film 11a composed of WSi is formed by sputtering described below so as to have a thickness of 2,000 Å (200 nm) or more in order to achieve a sufficient light-blocking effect. In this embodiment, the lower light-shading films 11a has a thickness of about 2,000 Å.

The first interlayer insulating film 12 formed of a silicon oxide film formed by plasma-enhanced chemical vapor deposition (CVD) with a tetraethoxysilane (TEOS) gas is disposed on the first layer including the lower light-shading films 11a. The first interlayer insulating film 12 electrically insulates the first layer from the second layer.

Each of the pixel-switching TFT 30 has a lightly doped drain (LDD) structure including the scan line 3a, a channel region 1a′, in which a channel is formed by an electric field from the scan line 3a, of a semiconductor layer 1a, a gate insulating film 2 that insulates the scan lines 3a from the semiconductor layer 1a, a lightly doped source region 1b (source-side LDD region) and a lightly doped drain region 1c (drain-side LDD region) of the semiconductor layer 1a, and a heavily doped source region 1d and a heavily doped drain region 1e of the semiconductor layer 1a. The pixel-switching TFT 30 preferably has the LDD structure as shown in FIG. 4 but may have an offset structure in which the lightly doped source region 1b and the lightly doped drain region 1c are not doped by implantation. Alternatively, the pixel-switching TFT 30 may be a self-aligned TFT produced by heavily implanting a dopant with a gate electrode 3a as a mask to form a heavily doped source region and a heavily doped drain region in a self-aligned manner.

The heavily doped drain region 1e of each TFT 30 is electrically connected to a corresponding one of the plurality of pixel electrodes 9a via a contact hole 8 passing through the second interlayer insulating film 4 and the third interlayer insulating film 7. The heavily doped source region 1d of each TFT 30 is electrically connected to the data line 6a via a contact hole 5 passing through the second interlayer insulating film 4. Furthermore, the heavily doped drain region 1e is electrically connected to a capacitor electrode 1f. The gate insulating film 2 as a dielectric film is held between the capacitor electrode 1f and the capacitor line 3b, thereby forming the storage capacitor 70.

The capacitor lines 3b and the scan lines 3a are each formed of the same polysilicon film. The dielectric film of each storage capacitor 70 and the gate insulating film 2 of each pixel-switching TFT 30 are each formed of the same oxide film formed at a high temperature. The capacitor electrode 1f, and the channel region 1a′, the source region 1d, the drain region 1e, and the like of the pixel-switching TFTs 30 are formed in the same semiconductor layer 1a.

On the other hand, a light-shading film 23 is formed on the surface of the liquid crystal layer 50 side of the opposite substrate 20 and is located in a region other than an opening region of each pixel. The light-shading film 23 is composed of a metal alloy, such as metal, e.g., Ti, Cr, W, Ta, Mo, or Pd, or a metal silicide. The light-shading film 23 has a light-blocking effect. In addition, the opposite electrode 21 formed of a transparent conductive thin film composed of ITO or the like is disposed on the light-shading film 23.

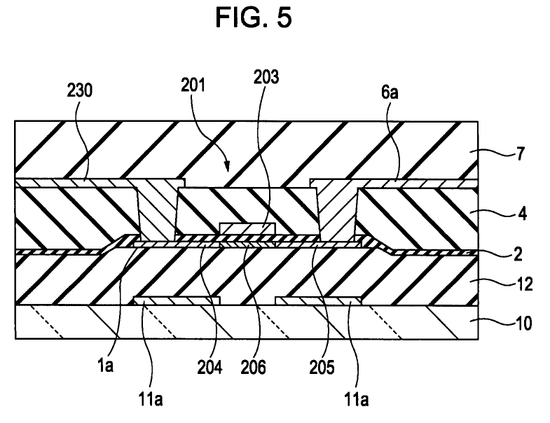

The TFTs 201 constituting the sampling circuit 200 each have the same structure as the TFT 30 formed in each pixel. The structure of each TFT 201 in the sampling circuit 200 will be described below with reference to FIG. 5. FIG. 5 is a cross-sectional view of the TFT 201 in the sampling circuit 200.

As shown in FIG. 5, the TFT 201 in the sampling circuit 200 is formed on the first interlayer insulating film 12 located on the lower light-shading film 11a formed on the TFT array substrate 10. The TFT 201 includes the semiconductor layer 1a on the first interlayer insulating film 12 and a gate 203 with the gate insulating film 2 provided therebetween, the gate insulating film 2 insulating the semiconductor layer 1a from the gate 203. The semiconductor layer 1a include a channel region 206, a source 204, and a drain 205. The TFT 201 has the same LDD structure as the TFT 30 in the pixel region.

The source 204 of each of the TFTs 201 is electrically connected to a corresponding one of the image signal lines 230 via a contact hole. The drain 205 is electrically connected to an end of a corresponding one of the data lines 6a. The gate 203 is electrically connected to a corresponding one of the sampling-circuit-driving signal lines 240 (not shown).

The lower light-shading film 11a located at the lower side of the TFT 201 is the same layer as the lower light-shading film 11a in the pixel region. The lower light-shading film 11a is formed of a WSi film having a thickness of about 2,000 Å. The lower light-shading film 11a composed of WSi is formed by sputtering described below.

A process of forming the TFTs 30 and 201 will be described below. The TFTs 30 and 201 are formed by the same process on the first interlayer insulating film 12 located on the lower light-shading film 11a.

A semiconductor layer such as amorphous silicon film is formed on the first interlayer insulating film 12. The resulting semiconductor layer is annealed at about 600° C. to 700° C. in a nitrogen atmosphere to form a solid-phase grown polysilicon film. The resulting polysilicon film is patterned to form the semiconductor layer 1a.

The semiconductor layer 1a is thermally oxidized at about 900° C. to 1,300° C. and preferably about 1,000° C. The gate insulating film 2 constituted by a multilayer high-temperature silicon oxide film (HTO film) is formed by reduced-pressure CVD or reduced-pressure CVD subsequent to the thermal oxidation. Then, the gate insulating film 2 is fired.

To control the threshold voltage Vth of the pixel-switching TFT 30, an n-channel region or a p-channel region is doped with a predetermined amount of a dopant such as boron by ion implantation or the like.

Then, a polysilicon film is deposited by reduced-pressure CVD or the like. Phosphorus is thermally diffused to impart conductivity to the polysilicon film. Alternatively, a doped silicon film in which P ions are introduced simultaneously with the formation of the polysilicon film may be used. The polysilicon film has a thickness of about 100 to 500 nm and preferably about 350 nm. After firing is performed, the scan lines 3a having a predetermined pattern including the gates of the TFTs 30 and 201 are formed by photolithography and etching.

For example, in the case where each TFT 30 is an n-channel type TFT having the LDD structure, in order to form a lightly doped source region and a lightly doped drain region in the semiconductor layer 1a, the semiconductor layer 1a is lightly doped with a dopant of a Group V element such as P (for example, at a dose of P ions of 1×10¹³ to 3×10¹³/cm²) with the scan line 3a (gate) as a mask. Thereby, the channel region 1a′ is formed in the semiconductor layer 1a located below the scan line 3a.

To form the heavily doped source region 1d and the heavily doped drain region 1e constituting the pixel-switching TFT 30, a resist layer having a plane pattern with a width wider than that of the scan line 3a is formed on the scan line 3a. The semiconductor layer 1a is heavily doped with a Group V element such as P (for example, at a dose of P ions of 1×10¹⁵ to 3×10¹⁵/cm²). Thereby, the TFTs 30 and 201 each having the lightly doped source and drain regions and the heavily doped source and drain regions are formed.

As described above, in the electro-optical apparatus 100 according to this embodiment, the TFTs 30 and 201 including the semiconductor layer 1a and the data lines 6a and the scan lines 3a as conductive layers are formed above the lower light-shading film 11a composed of WSi. To form the TFTs 30 and 201, high-temperature heat treatment, such as annealing, in which the temperature is raised to 600° C. or more, is performed more than once.

The as-deposited WSi film formed by sputtering has an amorphous structure. The WSi film is recrystallized at a high temperature of about 430° C. or higher. Internal stress is generated in the WSi film during the crystallization of the WSi film.

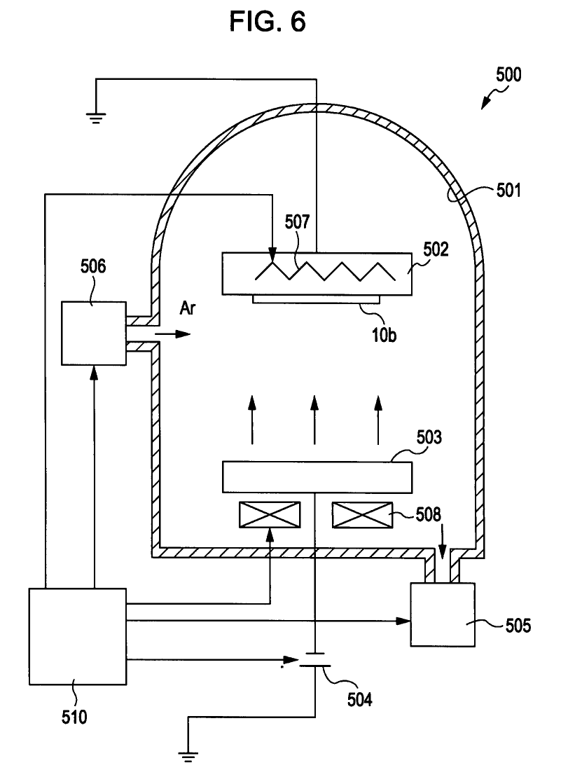

A sputtering apparatus 500, which is used as an apparatus for producing the electro-optical apparatus according to this embodiment, for forming the WSi film as the lower light-shading film 11a will be described below with reference to FIG. 6. FIG. 6 is a schematic cross-sectional view illustrating the structure of the sputtering apparatus according to this embodiment.

The sputtering apparatus 500 is used to form a thin film on a substrate by DC magnetron sputtering. In the description below, to form the WSi film on a surface of a wafer 10b as a substrate to be used to form the electro-optical apparatus, tungsten (W) and silicon (Si) are sputtered with the sputtering apparatus 500. The wafer 10b is in a state before the TFT array substrate 10 of the electro-optical apparatus 100 is cut.

The sputtering apparatus 500 includes a vacuum chamber 501 as a vacuum tank capable of being reduced to a predetermined degree of vacuum with a vacuum pump 505 as an evacuator, a target 503 placed in the vacuum chamber, and a substrate holder 502 that supports the wafer 10b opposite the target 503. The vacuum chamber 501 is provided with a gas supply unit 506 that supplies an argon (Ar) gas, which is an inert gas, to the vacuum chamber 501 at a predetermined flow rate.

The target 503 is produced by sintering a mixture containing tungsten and silicon in a predetermined mixing ratio. The target 503 is connected to a power supply controller 504. The target 503 is supplied with predetermined pulsed dc power from the power supply controller 504. An electromagnet 508 that generates a magnetic field is disposed on a side of the target 503 opposite the side adjacent to the wafer 10b. The substrate holder 502 has a mechanism to support one or more wafers 10b. The substrate holder 502 is provided with a heater 507 as a heating unit therein. The heater 507 is a unit that heats the wafer 10b to a predetermined temperature by heat conduction from heating wire or radiant heat from an infrared lamp.

The vacuum pump 505, the gas supply unit 506, the power supply controller 504, the electromagnet 508, and the heater 507 are electrically connected to a controller 510 as a controlling unit. The controller 510 controls operation thereof. The sputtering apparatus 500 has a mechanism to open and close the vacuum chamber 501 and a transport unit that transports the wafer 10b from and to the vacuum chamber 501 (not shown).

A method for producing the tungsten silicide (WSi) film with the sputtering apparatus 500 having the above-described structure will be described below. The operation of the sputtering apparatus 500 is automatically performed under the control of the controller 510.

The wafer 10b is transported into the vacuum chamber 501 with the transport unit and is then supported by the substrate holder 502. The vacuum chamber 501 is hermetically sealed and is then evacuated with the vacuum pump 505 to a predetermined degree of vacuum. The vacuum chamber 501 is supplied with an argon gas from the gas supply unit 506 and is thus in an argon atmosphere. In addition, powder is applied to the electromagnet 508 to generate a magnetic field around the target 503.

The power supply controller 504 supplies DC powder to the target 503 in the argon atmosphere at a predetermined degree of vacuum, thereby producing a discharge to produce a plasma on the wafer 10b side of the target 503. The plasma is produced around the target 503 by the magnetic field generated by the electromagnet 508. The bombardment of the target 503 with plasma-induced argon ions ejects sputtered particles composed of tungsten and silicon to deposit the particles on the wafer 10b. Thereby, the WSi film is formed on the wafer 10b.

In sputtering according to this embodiment, a value obtained by dividing the thickness (angstrom: Å) of the WSi film to be formed into the lower light-shading film 11a by the time (second: s) required for the film formation, i.e., the thickness of the WSi film deposited per second, is referred to as an “average deposition rate”. The unit of the average deposition rate is defined as Å/s.

The average deposition rate of the WSi film deposited with the sputtering apparatus 500 depends on power applied to the target 503, the degree of vacuum in the vacuum chamber 501, the flow rate of the argon gas, and magnetic force generated by the electromagnet 508. The average deposition rate of the WSi film is controlled by the controller 510 to a predetermined value.

In this embodiment, as described in detail below, the average deposition rate of the WSi film is equal to or higher than an average deposition rate at the limit of discharge maintenance in sputtering and 35 Å/s or less and preferably 30 Å/s or less.

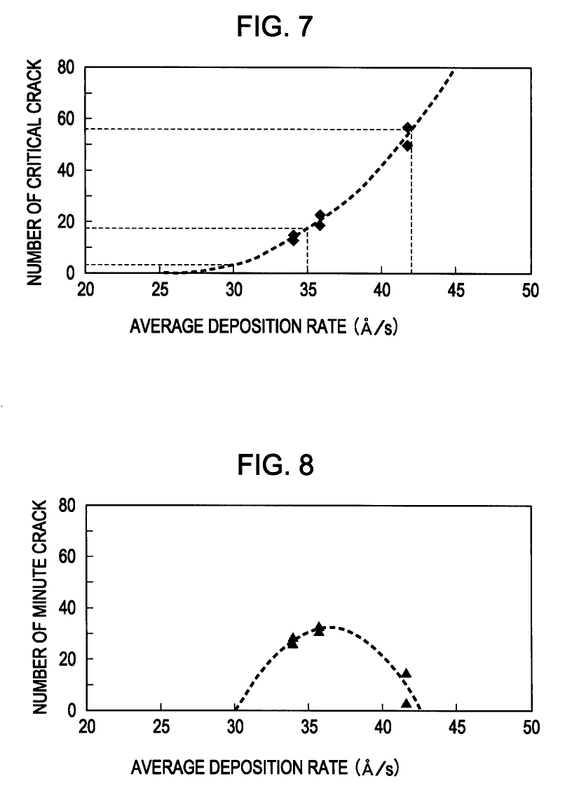

Effects of this embodiment will be described in detail below. FIGS. 7 and 8 each show the results of experiments performed to study the relationship between the average deposition rate of the WSi film and the number of cracks in the wafer 10b and to determine the average deposition rate of the WSi film. Hereinafter, a crack which is caused by internal stress in the WSi film after the wafer 10b is subjected to heat treatment and which breaks the scan line 3a or a conductive layer to be formed into the gates 203 of the TFTs 201 is referred to as a “critical crack”. Furthermore, a crack which is caused by internal stress in the WSi film after the wafer 10b is subjected to heat treatment and which does not break the scan line 3a or a conductive layer to be formed into the gates 203 of the TFTs 201 because of its small size is referred to as a “minute crack”. FIG. 7 is a graph showing the relationship between the average deposition rate of the WSi film and the number of critical cracks. FIG. 8 is a graph showing the relationship between the average deposition rate of the WSi film and the number of minute cracks.

In FIG. 7, the horizontal axis of the graph indicates the average deposition rate of the WSi film formed on the wafer 10b. The vertical axis of the graph indicates the number of critical cracks per wafer 10b. In FIG. 8, the horizontal axis of the graph indicates the average deposition rate of the WSi film formed on the wafer 10b. The vertical axis of the graph indicates the number of minute cracks per wafer 10b.

As shown in FIGS. 7 and 8, the results demonstrated that a smaller average deposition rate reduced the number of critical cracks and the number of minute cracks per wafer 10b.

Hitherto, the average deposition rate of the WSi film, serving as the lower light-shading film 11a, formed by sputtering is 41 to 42 Å/s. As shown in FIG. 7, an average deposition rate of the WSi film of 35 Å/s or less results in a reduction in the number of critical cracks that break the conductive layer to ⅓ of that in the known art. This may be because the formation of the WSi film at an average deposition rate lower than that in the known art allows the structure of the WSi film formed by sputtering to approach the structure of the WSi film crystallized by heat treatment, thereby reducing internal stress in the WSi film due to crystallization. As described above, in accordance with this embodiment, the number of critical cracks is suppressed to ⅓ of that in the known art, thereby markedly suppressing the occurrence of the malfunction of the electro-optical apparatus 100 due to the crack in the conductive layer and the semiconductor layer. The WSi film to be formed into the lower light-shading film 11a has a thickness of 2,000 Å. Thus, the lower light-shading film 11a has a sufficient light-blocking effect. Furthermore, the WSi film to be formed into the lower light-shading film 11a is formed by a single sputtering process similar to the known art. Thus, there is no need to increase the number of steps.

The average deposition rate of the WSi film is preferably 30 Å/s or less, thus reducing the number of critical cracks to 1/10 or less of that in the known art. Furthermore, no minute crack occurs. The occurrence of the minute crack does not affect the conductive layer or the semiconductor layer. In addition, the occurrence of the minute crack does not directly affect the occurrence of the malfunction of the electro-optical apparatus 100. However, the minute crack may extend to the conductive layer and the semiconductor layer in response to the fixation and use conditions of the electro-optical apparatus 100, i.e., stress applied from the outside and heat cycle. Namely, the presence of the minute crack degrades the reliability of the electro-optical apparatus. Thus, the occurrence of the minute crack eliminated by setting the average deposition rate of the WSi film at 30 Å/s or less further improves the reliability of the electro-optical apparatus.

Furthermore, an average deposition rate of the WSi film of 27 Å/s or less eliminates the occurrence of both critical crack and minute crack due to the internal stress in the WSi film and is thus more preferred. The sputtering apparatus cannot maintain a discharge and cannot stably generate sputtered particles unless dc power is sufficiently supplied. From the viewpoint of the crack, a lower average deposition rate of the WSi film results in satisfactory film quality. To achieve stable film formation, the average deposition rate needs to be equal to or higher than an average deposition rate at the limit of discharge maintenance in sputtering. In the sputtering apparatus 500, for example, the average deposition rate at the limit of discharge maintenance was 7 Å/s.

In this embodiment, the WSi film is formed by sputtering while the wafer 10b as a substrate to be used to form the electro-optical apparatus is not heated. Alternatively, the WSi film may be formed by sputtering while the surface of the wafer 10b on which the WSi film is formed is heated at 250° C. to 400° C. with heater 507. In this way, WSi is deposited on the surface of the wafer 10b heated to a temperature close to the crystallization temperature of WSi; hence, a dense WSi film can be formed compared with the case without heating. As a result, the structure of the WSi film formed by sputtering approaches the structure of the WSi film crystallized by subsequent heat treatment, thereby further reducing internal stress in the WSi film after heat treatment and thus further suppressing the occurrence of a crack due to the internal stress in the WSi film.

In the sputtering apparatus 500, the average deposition rate of the WSi film is generally controlled by controlling power supplied from the power supply controller 504 to the target 503. However, the average deposition rate of the WSi film may be controlled by another method. In particular, when a lower average deposition rate of the WSi film is achieved, there is a limit to the minimum power to maintain a discharge for sputtering.

Thus, pulsed power may be supplied to the target 503 to set the average deposition rate of the WSi film at 35 Å/s or less and preferably 30 521 /s or less. In this case, the average deposition rate of the WSi film depends on the pulse width and the frequency of dc power supplied to the target 503. Consequently, the average deposition rate of the WSi film can be easily controlled with a simple structure.

Furthermore, for example, the average deposition rate of the WSi film may be controlled by power supplied to the electromagnet 508, i.e., by controlling a magnetic field generated by the electromagnet 508. In this case, while a discharge for sputtering is maintained in the same way as in the known art, an on/off operation of power supplied to the electromagnet 508 changes an plasma state around the target 503 to control the number of sputtered particles ejected from the target 503. In this case, the average deposition rate of the WSi film can be controlled regardless of the minimum power to maintain a discharge for sputtering and can also be achieved with a simple structure.

The aspect of the invention relates to technical fields of electrophoretic devices, such as electronic paper, and electro-optical apparatuses, such as electro-luminescence (EL) displays and devices including electron emission components (field emission display and surface-conduction electron-emitter display), in addition to the active matrix liquid crystal display according to this embodiment.

The invention is not limited to the above-described embodiments. Various modifications may be made within the scope of the gist of claims and specification as a whole and of the spirit of the invention. A method including such modifications for producing an electro-optical apparatus is also included in the technical range of the invention.

What is claimed is:

1. A method for producing an electro-optical apparatus comprising:
forming a WSi film by sputtering including bombarding a target with ions of a plasma atmosphere in a vacuum chamber under reduced pressure so that particles are emitted from the target and deposited on a substrate to be used to form the electro-optical apparatus, the WSi film being formed at an average deposition rate in a range from the average deposition rate at the limit of discharge maintenance in sputtering to and including 35 Å/s.

2. The method for producing an electro-optical apparatus according to claim 1, wherein the average deposition rate of the WSi film is equal to or higher than an average deposition rate at the limit of discharge maintenance in sputtering and 30 Å/s or less.

3. The method for producing an electro-optical apparatus according to claim 1, wherein the WSi film is formed while the substrate is heated in the range of 250° C. to 400° C. in the vacuum chamber.

4. The method for producing an electro-optical apparatus according to claim 1, wherein magnetron sputtering is used, the position of the generation of the plasma of the atmosphere injected into the vacuum chamber is controlled by using a magnetic field generated by an electromagnet, and the average deposition rate of the WSi film is controlled by controlling the strength of the magnetic field generated by the electromagnet.

5. The method for producing an electro-optical apparatus according to claim 1, wherein the average deposition rate at the limit of discharge maintenance in sputtering is in the range of 7 Å/s to 35 Å/s.
